(19) United States
(12) Patent Application Publication
(10) Pub. No.: US 2012/0164784 A1
(43) Pub. Date: Jun. 28, 2012

(54) INTEGRATED DEPOSITION OF THIN FILM LAYERS IN CADMIUM TELLURIDE BASED PHOTOVOLTAIC MODULE MANUFACTURE

(75) Inventors: Scott Daniel Feldman-Peabody, Golden, CO (US); Russell Weldon Black, Longmont, CO (US); Robert Dwayne Gossman, Aurora, CO (US); Brian Robert Murphy, Evergreen, CO (US); Mark Jeffrey Pavol, Arvada, CO (US)

(73) Assignee: PRIMESTAR SOLAR, INC., Arvada, CO (US)

(21) Appl. No.: 12/977,139

(22) Filed: Dec. 23, 2010

(51) Int. Cl. H01L 31/18; C23C 14/34

(52) U.S. Cl. 438/84; 204/298.25; 257/E31.015

(57) ABSTRACT

Apparatus and processes for thin film deposition of semiconducting layers in the formation of cadmium telluride thin film photovoltaic device are provided. The apparatus includes a series of integrally connected chambers, such as a load vacuum chamber connected to a load vacuum pump; a sputtering deposition chamber; a vacuum buffer chamber; and, a vapor deposition chamber. A conveyor system is operably disposed within the apparatus and configured for transporting substrates in a serial arrangement into and through the load vacuum chamber, the sputtering deposition chamber, the vacuum buffer chamber, and the vapor deposition chamber at a controlled speed. The sputtering deposition chamber; the vacuum buffer chamber; and the vapor deposition chamber are integrally connected such that the substrates being transported through the apparatus are kept at a system pressure less than about 760 Torr.

### FIELD OF THE INVENTION

The subject matter disclosed herein relates generally to methods and systems for depositing thin films during manufacture of cadmium telluride photovoltaic devices. More particularly, the subject matter disclosed herein relates generally to integrated systems for the deposition of a resistive transparent buffer layer, a cadmium sulfide layer, and a cadmium telluride layer during manufacture of cadmium telluride photovoltaic devices, and their methods of use.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., a positive, electron accepting layer) and the CdS layer acts as a n-type layer (i.e., a negative, electron donating layer). Free carrier pairs are created by light energy and then separated by the p-n heterojunction to produce an electrical current.

During the production of CdTe PV modules, the surface of the CdTe PV module is exposed to the room atmosphere after application of the resistive transparent buffer layer and the cadmium sulfide layer while being transported from deposition process to deposition process. This exposure can result in the introduction of additional atmospheric materials into the resistive transparent buffer layer and/or the cadmium sulfide layer. These materials can lead to the introduction of impurities in the CdTe PV module. Additionally, the room atmosphere naturally varies over time, adding a variable to a large-scale manufacturing process of the CdTe PV modules. Such impurities and additional variables can lead to inconsistent CdTe PV modules from the same manufacturing line and process.

Thus, a need exists for methods and systems for reducing the introduction of impurities and additional variables into a large-scale manufacturing process of making the CdTe PV modules.

### BRIEF DESCRIPTION OF THE INVENTION

Aspects and advantages of the invention will be set forth in part in the following description, or may be obvious from the description, or may be learned through practice of the invention.

Apparatuses are generally provided for thin film deposition of semiconducting layers in the formation of cadmium telluride thin film photovoltaic device. The apparatus includes a series of integrally connected chambers. The apparatus includes a load vacuum chamber connected to a load vacuum pump configured to reduce the pressure within the load vacuum chamber to an initial load pressure; a sputtering deposition chamber; a vacuum buffer chamber connected to a buffer vacuum pump configured to control the pressure within the vacuum buffer chamber; and, a vapor deposition chamber. A conveyor system is operably disposed within the apparatus and configured for transporting substrates in a serial arrangement into and through the load vacuum chamber, into and through the sputtering deposition chamber, into and through the vacuum buffer chamber, and into and through the vapor deposition chamber at a controlled speed. The sputtering deposition chamber; the vacuum buffer chamber; and the vapor deposition chamber are integrally connected such that the substrates being transported through the apparatus are kept at a system pressure less than about 760 Torr.

Processes are also provided for manufacturing a thin film cadmium telluride thin film photovoltaic device. A substrate is first transferred into a load vacuum chamber connected to a load vacuum pump, and a vacuum is drawn in the load vacuum chamber until an initial load pressure is reached in the load vacuum chamber. The substrate can then be transported from the load vacuum chamber into a sputtering deposition chamber, where a target including cadmium sulfide can be sputtered to deposit a cadmium sulfide layer on the substrate via a plasma ejecting atoms from the target to deposit onto the substrate. The substrate can then be transported from the sputtering deposition chamber into a vacuum buffer chamber connected to a buffer vacuum pump, where a vacuum can be drawn to control a buffer atmosphere. The substrate can then be transported from the vacuum buffer chamber into a vapor deposition chamber comprising a source material (e.g., cadmium telluride), such that a cadmium telluride layer can be deposited on the cadmium sulfide layer by heating the source material to produce source vapors that deposit onto the cadmium sulfide layer on the substrate. The substrate can be transported through the load vacuum chamber, the sputtering deposition chamber, the vacuum buffer chamber, and the vapor deposition chamber at a system pressure at a pressure less than about 760 Torr.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary deposition system for sequentially depositing two thin film layers on a substrate;

FIG. 2 shows a general schematic of a cross-sectional view of one exemplary deposition system for depositing multiple thin film layers on a substrate;

FIG. 3 shows a general schematic of a cross-sectional view of another exemplary deposition system for depositing multiple thin film layers on a substrate;

FIG. 4 shows a general schematic of a cross-sectional view of yet another exemplary deposition system for depositing multiple thin film layers on a substrate;

FIG. 5 shows a general schematic of a cross-sectional view of still another exemplary deposition system for depositing multiple thin film layers on a substrate; and,

FIG. 6 shows a general schematic of a cross-sectional view of yet another exemplary deposition system for depositing multiple thin film layers on a substrate;

FIG. 7 shows a diagram of an exemplary process of depositing multiple thin film layers on a substrate to form a cadmium telluride based PV device;

FIG. 8 is a cross-sectional view of an embodiment of an exemplary vapor deposition apparatus in a first operational configuration for use in a vapor deposition chamber of the deposition system; and,

FIG. 9 is a cross-sectional view of the embodiment of FIG. 9 in a second operational configuration.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Generally speaking, methods and systems are presently disclosed for increasing the efficiency and/or consistency of in-line manufacturing of cadmium telluride thin film photovoltaic devices. Specifically, at least one sputtering deposition chamber and at least one vapor deposition chamber, separated by a buffer vacuum chamber, are present in the systems and methods. The sputtering deposition chamber(s), the vacuum buffer chamber(s), and the vapor deposition chamber(s) are integrally interconnected such that substrates passing through and between these chambers are not exposed to the outside atmosphere.

In one particular embodiment, integrated systems and methods for thin film deposition of the resistive transparent buffer layer, the cadmium sulfide layer, and the cadmium telluride layer on the substrate are generally disclosed. For example, the integrated systems and methods can be utilized to deposit a cadmium sulfide layer on a substrate and a cadmium telluride layer on the cadmium sulfide layer. For example, the cadmium sulfide layer can be sputtered onto the substrate from a sputtering target (e.g., including cadmium sulfide) in a sputtering chamber. The substrate can then be transferred from the sputtering chamber to a vacuum buffer chamber to remove any particles from the substrate and/or chamber atmosphere before depositing subsequent layers (e.g., any excess cadmium sulfide particles in the atmosphere). The substrate can then be transferred into a vapor deposition chamber for deposition of a source material (e.g., cadmium telluride) onto the cadmium sulfide layer on the substrate. Optionally, a resistive transparent buffer layer (“RTB layer”) can be deposited on the substrate prior to depositing the cadmium sulfide layer. For instance, the RTB layer can be sputtered from a RTB target (e.g., including a zinc tin oxide) onto a conductive transparent oxide layer on the substrate.

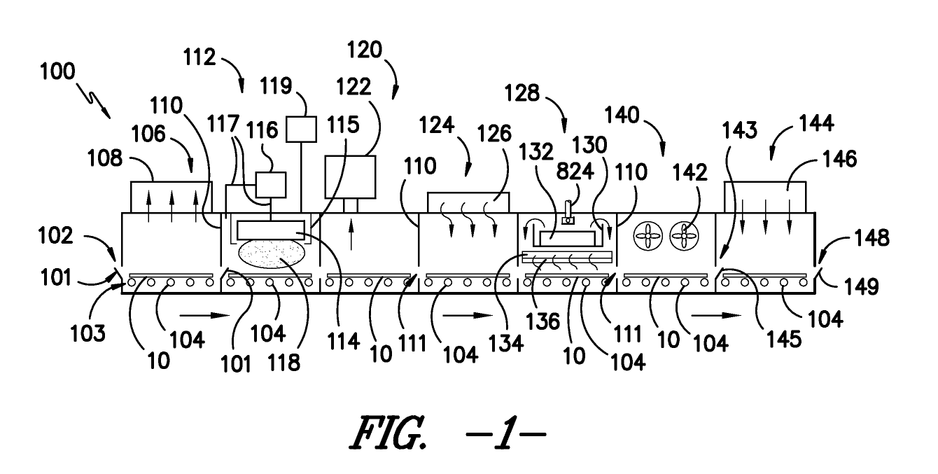

FIG. 1 shows an integrated deposition system 100 including a load vacuum chamber 106, a sputtering chamber 112, a vacuum buffer chamber 120, and a vapor deposition chamber 128. Each of the chambers are integrally interconnected together such that the substrates 10 passing through the system 100 are substantially protected from the outside environment. In other words, the chambers 106, 112, 120, and 128 of the system 100 are directly integrated together such that a substrate 10 exiting one chamber immediately enters the adjacent section directly, without exposure to the room atmosphere. Thus, the substrates 10 can be protected from outside contaminants being introduced into the thin films, resulting in more uniform and efficient devices. Of course, other intermediary chambers may be included within the system 100, as long as the system remains integrally interconnected to the other chambers of the system 100.

Through the integration of these deposition chambers into a single system, the energy consumption required for the deposition of the sputtered layer (e.g., a RTB layer or CdS layer) and a vapor deposited layer (e.g., a CdS layer or a CdTe layer) can be reduced, when compared from separated deposition systems, during the manufacturing of a cadmium telluride thin film device. For instance, once the load vacuum is drawn in the load vacuum chamber 106, no need for an additional load vacuum chambers exists, since the system pressure can remain below atmospheric pressure (i.e., about 760 Torr) through the sputtering chamber 112, the vacuum buffer chamber 120, and the vapor deposition chamber 128. For example, in certain embodiments, the system pressure can remain below 250 Torr, such as about 10 mTorr to about 100 Torr. In one particular embodiment, the system pressure can remain below the initial load vacuum pressure (e.g., less than about 250 mTorr). For example, in one embodiment, the system pressure can be substantially constant through the sputtering chamber 112, the vacuum buffer chamber 120, and the vapor deposition chamber 128 (and any chambers positioned therebetween).

Referring to FIG. 1, individual substrates 10 enter the integrated deposition system 100 through the entry slot 102 onto the transport system 103. The transport system 103 is configured to move the individual substrates 10 through the deposition system 100 at the desired rate of speed (e.g., a substantially uniform rate). As shown, the transport system 103 includes a plurality of rollers 104, but can also be a conveyor system including conveyor belts, a rail system including oppositely positioned rails, or any other suitable transport system for moving the substrates 10 through the deposition system 100.

The substrates 10 can be transferred by the transport system 103 between adjacent chambers through the slit 111 defined in each internal wall 110 between chambers. For example, a first internal wall 110 is shown separating the load vacuum chamber 106 from the sputtering deposition chamber 112 and defining the slit 111 such that the substrates 10 can pass from the load vacuum chamber 106 into the sputtering deposition chamber 112. The slit 111 is sized and shaped to allow the substrates 10 to pass therethrough, while effectively separating the load vacuum chamber 106 and the sputtering deposition chamber 112. For example, the slit 111 can define a height that is from about 105% to about 250% of the thickness of the substrates 201, such as from about 125% to about 200% of the thickness of the substrates 201. The slit 111 can be defined across the entire length of the internal wall 110, or may be sized according to the width of the devices 10. In particular embodiments, the slit 111 may have a length that is from about 101% to about 150% of the width of the substrates 10. As such, the source materials (e.g., ejected atoms) in the sputtering deposition chamber 112 can substantially remain within the chamber 112, and the source material (e.g., vapors) can substantially remain within the vapor deposition chamber 128. Thus, the atmospheres in the load vacuum chamber 106 and the first sputtering deposition chamber 112 can be substantially separated from each other, especially when a constant line of substrates 10 are transported through the slit 111 to effectively close any gap in the internal wall 110. However, the process gas(es), such as an inert gas like argon, can move between the chambers of the system.

In one particular embodiment, a slit door (not shown) can be included to open when a substrate 10 is within the slit 111 to allow passage therethrough, while closing the slit 111 when no substrate is present within the slit 111 (similarly to the flap 101 of the entry slot 102 discussed below).

As shown in FIG. 1, the individual substrates 10 first enter the load vacuum chamber 106 through the entry slot 102. The entry slot 102 defines a flap 101 that can close to separate the internal atmosphere within the load vacuum chamber 106 from the outside environment. The load vacuum chamber 106 is connected to a load vacuum pump 108 configured to draw a load pressure within the load vacuum chamber 106. Specifically, the load vacuum pump 108 can reduce the pressure within the load vacuum chamber 106 to an initial load pressure of about 1 mTorr to about 250 mTorr, such as about 10 mTorr to about 100 mTorr.

Although shown as a single load vacuum chamber 106, a plurality of vacuum chambers can be utilized to sequentially reduce the system pressure to the desired amount. For example, a rough vacuum chamber(s) can first reduce the pressure to a manageable pressure (e.g., about 10 mTorr to about 250 mTorr), followed by a fine vacuum chamber(s) that can reduce the pressure to an increased vacuum. For instance, the fine vacuum chamber(s) can reduce the pressure to about 1×10⁻⁷ Torr to about 1×10⁻⁴ Torr, and then backfilled with an inert gas (e.g., argon) in a subsequent chamber within the system 10 (e.g., within the sputtering deposition chamber 112) to a deposition pressure (e.g., about 10 mTorr to about 100 mTorr).

The substrates 10 can be transferred from the load vacuum chamber 106 to the sputtering deposition chamber 112 through slit 111 defined in the internal wall 110. Sputtering deposition generally involves ejecting material from a target, which is the material source, and depositing the ejected material onto the substrate to form the film. DC sputtering generally involves applying a direct current to a metal target (i.e., the cathode) positioned near the substrate (i.e., the anode) within a sputtering chamber to form a direct-current discharge. The sputtering chamber can have a reactive atmosphere (e.g., including sulfur in addition to oxygen, nitrogen, etc.) that forms a plasma field between the metal target and the substrate. Other inert gases (e.g., argon, etc.) may also be present. The pressure of the reactive atmosphere can be between about 1 mTorr and about 20 mTorr for magnetron sputtering. The pressure can be even higher for diode sputtering (e.g., from about 25 mTorr to about 100 mTorr). When metal atoms are released from the target upon application of the voltage, the metal atoms deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps. Conversely, RF sputtering involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) which may or may not contain reactive species (e.g., oxygen, nitrogen, etc.) having a pressure between about 1 mTorr and about 20 mTorr for magnetron sputtering. Again, the pressure can be even higher for diode sputtering (e.g., from about 25 mTorr to about 100 mTorr).

As shown, the sputtering deposition chamber 112 generally includes a target 114 connected to a power source 116 (e.g., a DC or RF power source) via wires 117. The power source 116 is configured to control and supply power (e.g., DC, RF, or pulsed DC power) to the sputtering deposition chamber 112. As shown, the power source 116 applies a voltage to the target 114 (acting as the cathode) to create a voltage potential between the target 114 and an anode formed by the shields 115 and the chamber walls 110, such that the substrates 10 is within the magnetic fields formed therebetween. Although only a single power source 116 is shown, the voltage potential can be realized through the use of multiple power sources coupled together.

The substrates 10 are generally positioned within the sputtering deposition chamber 112 such that a thin film layer (e.g., a RTB layer or a CdS layer) is formed on the surface of the substrates 10 facing the target 114. A plasma field 118 is created once the sputtering atmosphere is ignited, and is sustained in response to the voltage potential between the target 114 and the chamber walls 110 acting as an anode. The voltage potential causes the plasma ions within the plasma field 118 to accelerate toward the target 114, causing atoms from the target 114 to be ejected toward the surface on the substrate 10. As such, the target 114 (also can be referred to as the cathode) acts as the source material for the formation of the thin film layer on the surface of the substrate 10 facing the target 114.

A sputtering atmosphere control system 119 can control the sputtering atmosphere within the sputtering deposition chamber 112, such as reducing to the sputtering pressure (e.g., about 10 to about 25 mTorr). Generally, the sputtering atmosphere control system 119 can provide an inert gas (e.g., argon) to the sputtering deposition chamber 112. Optionally, the sputtering atmosphere can also include oxygen, allowing oxygen particles of the plasma field 118 to react with the ejected target atoms to form a thin film layer that includes oxygen.

For example, the sputtering deposition chamber 112 can be utilized to form a cadmium sulfide layer on the substrate. In this embodiment, the target 114 can be a ceramic target, such as of cadmium sulfide. Additionally, in some embodiments, a plurality of targets 114 can be utilized. A plurality of targets 114 can be particularly useful to form a layer including several types of materials (e.g., co-sputtering).

After sputtering a thin film on the substrates 10 in the sputtering deposition chamber 112, the substrates can be transferred to a vacuum buffer chamber 120. A buffer vacuum pump 122 can draw a vacuum within the vacuum buffer chamber 120 to reduce the pressure within the vacuum buffer chamber 120 to a buffer pressure. Generally, the buffer vacuum pump 122 can remove any spill-over particles from the sputtering deposition chamber 112 from the buffer chamber atmosphere. Thus, the vacuum buffer chamber 120 can effectively separate the sputtering atmosphere within the sputtering deposition chamber 112 and the vapor deposition atmosphere within the vapor deposition chamber 128. Additionally, the vacuum buffer pump 122 can be configured to remove excess material from the substrate exiting the sputtering deposition chamber. In one embodiment, a backfill gas port configured to provide an inert gas to the vapor deposition temperature can be included within the vacuum buffer pump 122.

Optionally, the substrates 10 can be transferred into and through a heating chamber 124 positioned between the sputtering deposition chamber 112 and the vapor deposition chamber 128, such as shown in FIG. 1 between the vacuum buffer chamber 120 and the vapor deposition chamber 128. The heating chamber 124 can include a heating element 126 configured to heat the substrates 10 to a vapor deposition temperature prior to entering the vapor deposition chamber 128, such as about 350° C. to about 600° C., depending on the parameters of the vapor deposition. In an alternative embodiment, the vacuum buffer chamber 120 can include heaters (not shown) instead of, or in addition to, the heating chamber 124.

The substrates 10 can then be transferred into and through the vapor deposition chamber 128 for deposition of a second thin layer on the substrate (and more specifically over the sputtered thin film layer on the substrate). The vapor deposition chamber 128 includes a receptacle 130 holding a source material 132. A heating manifold 134 can be positioned between the receptacle 130 to heat the source material 132 within the receptacle 130 into vapor. The vapor can pass over the receptacle 130 and through passages defined in the heating manifold 134 and holes defined in the underlying distribution plate 136 for deposition of a second thin film over the first thin film on the substrate.

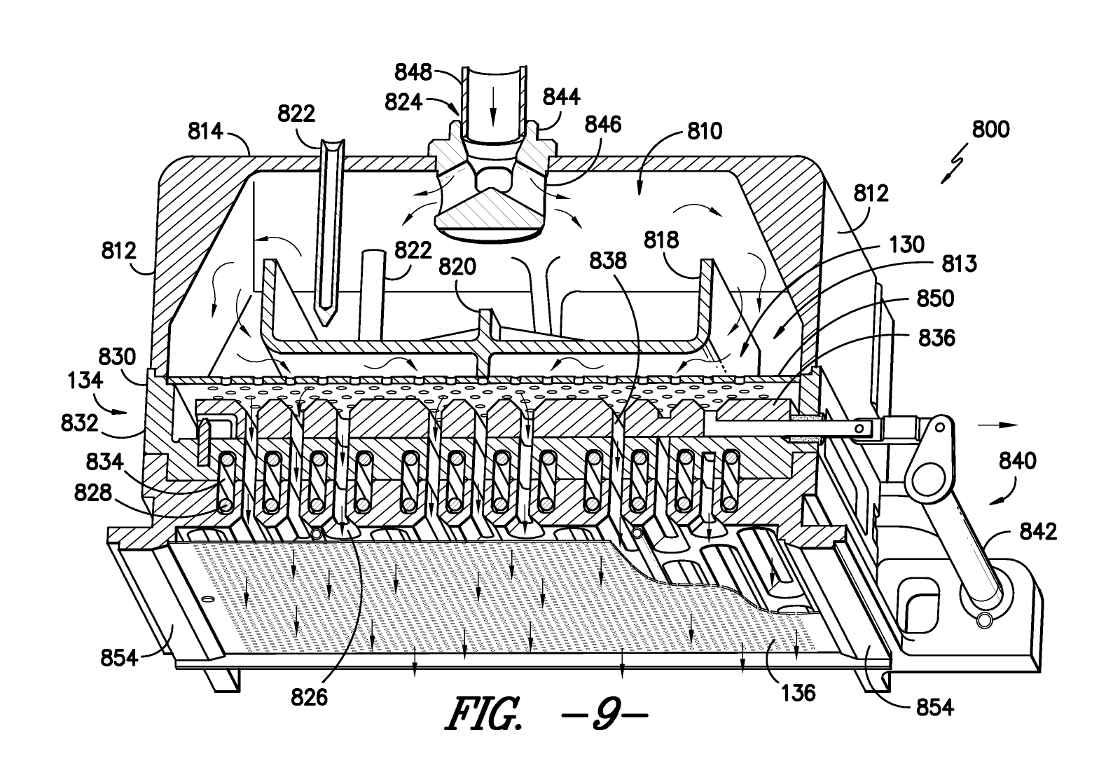

FIGS. 8 and 9 show a detailed view of a vapor deposition apparatus 800 for use in the vapor deposition chamber 128 in the integrated deposition system 100 according to one embodiment. The apparatus 800 includes a deposition head 810 defining an interior space in which a receptacle 130 is configured for receipt of a granular source material (not shown), such as cadmium telluride for the vapor deposition of a cadmium telluride thin film layer. The granular source material may be supplied by a feed device or system 824 via a feed tube 848. The feed tube 848 is connected to a distributor 844 disposed in an opening in a top wall 814 of the deposition head 810. The distributor 844 includes a plurality of discharge ports 846 that are configured to evenly distribute the granular source material into the receptacle 130. The receptacle 130 has an open top and may include any configuration of internal ribs 820 or other structural elements.

In the illustrated embodiment, at least one thermocouple 822 is operationally disposed through the top wall 814 of the deposition head 810 to monitor temperature within the deposition head 810 adjacent to or in the receptacle 130.

The deposition head 810 also includes longitudinal end walls 812 and side walls 813. The receptacle 130 has a shape and configuration such that the transversely extending end walls 818 of the receptacle 130 are spaced from the end walls 812 of the head chamber 810. The longitudinally extending side walls (not shown) of the receptacle 130 lie adjacent to and in close proximation to the side walls 113 of the deposition head 810 so that very little clearance exists between the respective walls. With this configuration, sublimated source material will flow out of the open top of the receptacle 130 and downwardly over the transverse end walls 818 as leading and trailing curtains of vapor over, as depicted by the flow lines in FIGS. 8 and 9. Very little of the sublimated source material will flow over the side walls (not shown) of the receptacle 130. The curtains of vapor are “transversely” oriented in that they extend across the transverse dimension of the deposition head 810, which is generally perpendicular to the conveyance direction of the substrates through the system.

A heated distribution manifold 134 is disposed below the receptacle 130. This distribution manifold 134 may take on various configurations within the scope and spirit of the invention, and serves to indirectly heat the receptacle 130, as well as to distribute the sublimated source material (i.e., the source material vapors) that flows from the receptacle 130. In the illustrated embodiment, the heated distribution manifold 134 has a clam-shell configuration that includes an upper shell member 830 and a lower shell member 832. Each of the shell members 830, 832 includes recesses therein that define cavities 834 when the shell members are mated together as depicted in FIGS. 8 and 9. Heater elements 828 are disposed within the cavities 834 and serve to heat the distribution manifold 134 to a degree sufficient for indirectly heating the source material within the receptacle 130 to cause sublimation of the source material. The heater elements 828 may be made of a material that reacts with the source material vapor and, in this regard, the shell members 830, 832 also serve to isolate the heater elements 828 from contact with the source material vapor. The heat generated by the distribution manifold 134 is also sufficient to prevent the sublimated source material from plating out onto components of the head chamber 810. Desirably, the coolest component in the head chamber 810 is the upper surface of the substrates 10 conveyed therethrough so as to ensure that the sublimated source material plates onto the substrate, and not onto components of the head chamber 810.

Still referring to FIGS. 8 and 9, the heated distribution manifold 134 includes a plurality of passages 826 defined therethrough. These passages have a shape and configuration so as to uniformly distribute the sublimated source material towards the underlying substrates 10.

In the illustrated embodiment, a distribution plate 136 is disposed below the distribution manifold 134 at a defined distance above a horizontal plane of the upper surface of an underlying substrate 10, as depicted in FIG. 1. This distance may be, for example, between about 0.3 cm to about 4.0 cm. In a particular embodiment, the distance is about 1.0 cm. The conveyance rate of the substrates below the distribution plate 136 may be in the range of, for example, about 10 mm/sec to about 40 mm/sec. In a particular embodiment, this rate may be, for example, about 20 mm/sec. The thickness of the CdTe film layer that plates onto the upper surface of the substrate 10 can vary within the scope and spirit of the invention, and may be, for example, between about 1 micron to about 5 microns. In a particular embodiment, the film thickness may be about 3 microns.

The distribution plate 136 includes a pattern of passages, such as holes, slits, and the like, therethrough that further distribute the sublimated source material passing through the distribution manifold 134 such that the source material vapors are uninterrupted in the transverse direction. In other words, the pattern of passages are shaped and staggered or otherwise positioned to ensure that the sublimated source material is deposited completely over the substrate 10 in the transverse direction so that longitudinal streaks or stripes of “un-coated” regions on the substrate are avoided.

As previously mentioned, a significant portion of the sublimated source material will flow out of the receptacle 130 as leading and trailing curtains of vapor. Although these curtains of vapor will diffuse to some extent in the longitudinal direction prior to passing through the distribution plate 136, it should be appreciated that it is unlikely that a uniform distribution of the sublimated source material in the longitudinal direction will be achieved. In other words, more of the sublimated source material will be distributed through the longitudinal end sections of the distribution plate 136 as compared to the middle portion of the distribution plate. However, as discussed above, because the transport system 103 can carry the substrates 10 through the system 100 at a constant (non-stop) linear speed, the upper surfaces of the substrates 10 will be exposed to the same deposition environment regardless of any non-uniformity of the vapor distribution along the longitudinal aspect of the apparatus 800. The passages 826 in the distribution manifold 134 and the holes in the distribution plate 136 ensure a relatively uniform distribution of the sublimated source material in the transverse aspect of the vapor deposition apparatus 800. So long as the uniform transverse aspect of the vapor is maintained, a relatively uniform thin film layer is deposited onto the upper surface of the substrates 10 regardless of any non-uniformity in the vapor deposition along the longitudinal aspect of the apparatus 800.

As illustrated in the figures, it may be desired to include a debris shield 850 between the receptacle 130 and the distribution manifold 134. This shield 850 includes holes defined therethrough (which may be larger or smaller than the size of the holes of the distribution plate 136) and primarily serves to retain any granular or particulate source material from passing through and potentially interfering with operation of the movable components of the distribution manifold 134, as discussed in greater detail below. In other words, the debris shield 850 can be configured to act as a breathable screen that inhibits the passage of particles without substantially interfering with vapors flowing through the shield 850.

The apparatus 800 desirably includes transversely extending seals 854 at each longitudinal end of the head chamber 810. The seals 854 can aid the slits 111 at the longitudinal ends of the vapor deposition chamber 128 to separate the vapor deposition atmosphere within the vapor deposition chamber 128 from adjacent chambers. These seals 854 are disposed at a distance above the upper surface of the substrates 10 that is less than the distance between the surface of the substrates 10 and the distribution plate 136. The seals 854 help to maintain the sublimated source material in the deposition area above the substrates. In other words, the seals 854 prevent the sublimated source material from “leaking out” through the longitudinal ends of the vapor deposition chamber 128. It should be appreciated that the seals 854 may be defined by any suitable structure. In the illustrated embodiment, the seals 854 are actually defined by components of the lower shell member 832 of the heated distribution manifold 134. It should also be appreciated that the seals 854 may cooperate with other structure of the vapor deposition apparatus 800 to provide the sealing function. For example, the seals may engage against structure of the underlying conveyor assembly in the deposition area.

The illustrated embodiment of FIGS. 8 and 9 includes a movable shutter plate 836 disposed above the distribution manifold 134. This shutter plate 836 includes a plurality of passages 838 defined therethrough that align with the passages 826 in the distribution manifold 134 in a first operational position of the shutter plate 836 as depicted in FIG. 9. As can be readily appreciated from FIG. 9, in this operational position of the shutter plate 836, the sublimated source material is free to flow through the shutter plate 836 and through the passages 826 in the distribution manifold 134 for subsequent distribution through the plate 136. Referring to FIG. 8, the shutter plate 836 is movable to a second operational position relative to the upper surface of the distribution manifold 134 wherein the passages 838 in the shutter plate 836 are misaligned with the passages 826 in the distribution manifold 134. In this configuration, the sublimated source material is blocked from passing through the distribution manifold 134, and is essentially contained within the interior volume of the head chamber 810. Any suitable actuation mechanism, generally 840, may be configured for moving the shutter plate 836 between the first and second operational positions. In the illustrated embodiment, the actuation mechanism 840 includes a rod 842 and any manner of suitable linkage that connects the rod 842 to the shutter plate 836. The rod 842 is rotated by any manner of mechanism located externally of the head chamber 810.

The shutter plate 836 is particularly beneficial in that, for whatever reason, the sublimated source material can be quickly and easily contained within the head chamber 810 and prevented from passing through to the deposition area above the conveying unit.

The substrates 10 can be transferred from the vapor deposition chamber 128 to a cooling chamber 140 including cooling elements 142 to return the substrates 10 to room temperature. Although shown with only a single cooling chamber 140, a series of cooling chambers can be utilized to systematically cool the substrates 10 to room temperature.

The substrates can then be passed into and through an exit lock chamber 144 through exit slit 143. The exit slit 143 can include a flap 145 to separate the exit atmosphere from the system atmosphere. As such, the substrates within the exit lock chamber 144 can be returned to room atmosphere through the exit atmosphere control 146 pumping air into the exit lock chamber 144 upon closing of the flap 145. Thus, the system atmosphere spanning from the load vacuum chamber 106 to the vapor deposition chamber 128 can be separated from the room atmosphere.

Although the system 100 shows only one sputtering deposition chamber 1112 and one vapor deposition chamber 128, for the deposition of two subsequent thin film layers on the substrates 10, additional deposition chambers (sputtering deposition and/or vapor deposition) can be included within the system 100 for the deposition of addition thin films on the substrates 10. Additionally, other treatment and/or heating chambers can be included within the system 100. For example, a heating chamber can be positioned between the vapor deposition chamber 128 and the cooling chamber 140.

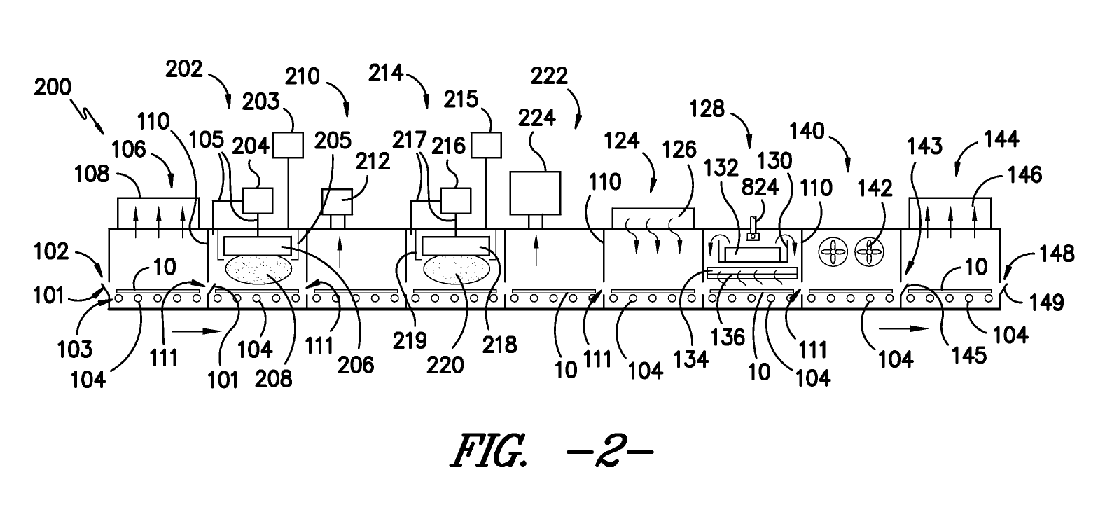

For example, FIG. 2 shows one particular embodiment of an integrated deposition system 200 utilized to sequentially deposit three thin film layers on the substrates 10 (e.g., a RTB layer, a cadmium sulfide layer over the RTB layer, and a cadmium telluride layer over the cadmium sulfide layer). The system 200 includes a first sputtering deposition chamber 202 into which the substrates 10 are transferred from the load vacuum chamber 106 via transport system 103. The first sputtering deposition chamber 202 includes a first power source 204 connected to a first target 206 via first wires 205. The sputtering atmosphere system 203 can control the sputtering atmosphere within the first sputtering deposition chamber 202. Upon ignition of the plasma 208 and the creation of a voltage potential between the first target 206 and the first shields 205 and chambers walls 110, atoms can be ejected from the target 206 onto the substrate 10.

After deposition of the first thin film layer in the first sputtering deposition chamber 202, the substrates 10 can be transferred into and through the first vacuum buffer chamber 210 connected to the first vacuum pump 212 through the slit 111 in the internal wall 110. The first vacuum buffer chamber 210 separates the first sputtering atmosphere in the first sputtering deposition chamber 202 from the second sputtering atmosphere in the second sputtering deposition chamber 214. As such, contamination between ejected atoms within the first sputtering deposition chamber 202 and the second sputtering deposition chamber 214 can be minimized.

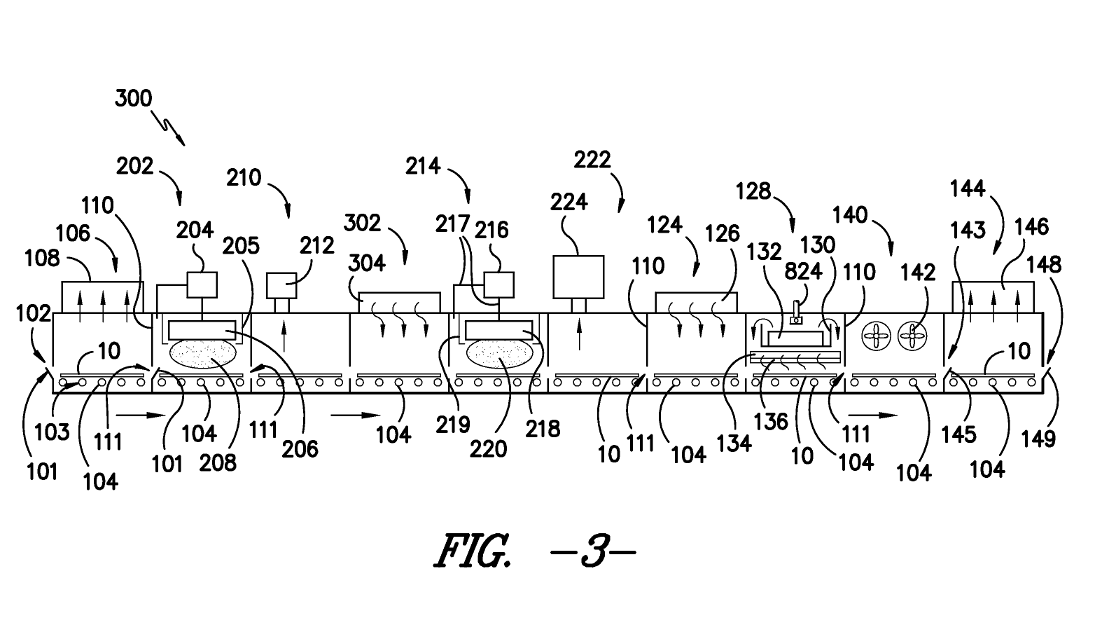

The substrates 10 can be transferred into and through the second sputtering deposition chamber 214 having the second power supply 216 connected to the second target 218 (protected by shields 219) via wires 217. The second sputtering atmosphere system 215 can control the second sputtering atmosphere within the second sputtering deposition chamber 214. The plasma 220 can eject atoms from the target 218 to deposit a second thin film (e.g., a cadmium sulfide layer) over the first thin film (e.g., the RTB layer) on the substrates 10 transported therethrough. In one particular embodiment, such as shown in the system 300 of FIG. 3, the second sputtering deposition chamber 214 can be heated sputtering of substrates 10 after passing through a sputtering heating chamber 302 connected to the heating elements 304 configured to heat the substrates 10 to a sputtering temperature.

A second vacuum buffer chamber 222 connected to a second vacuum pump 224 can draw a second buffer atmosphere between the second vacuum buffer chamber 222 and subsequent chambers (e.g., the optional heating chamber 124 or the vapor deposition chamber 128).

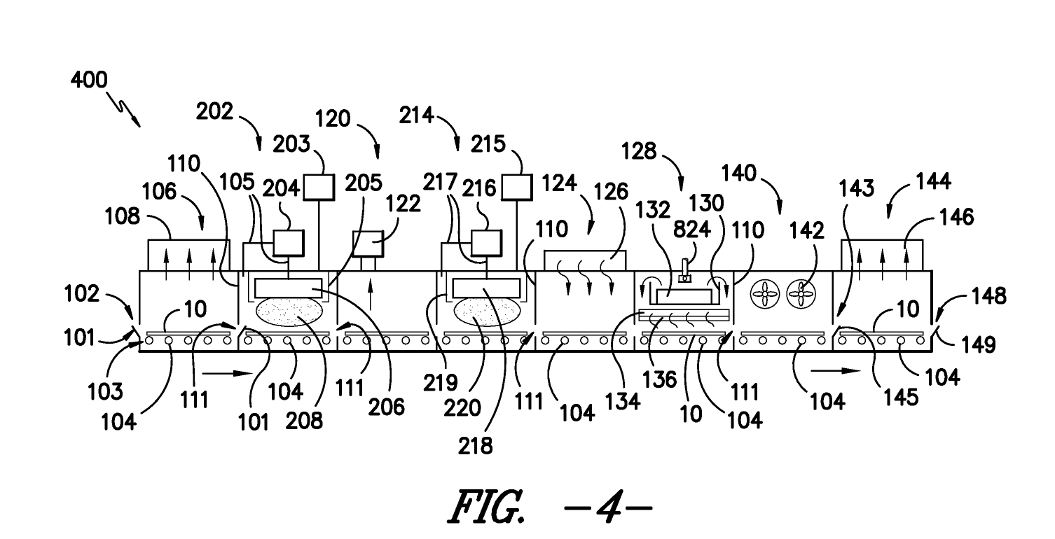

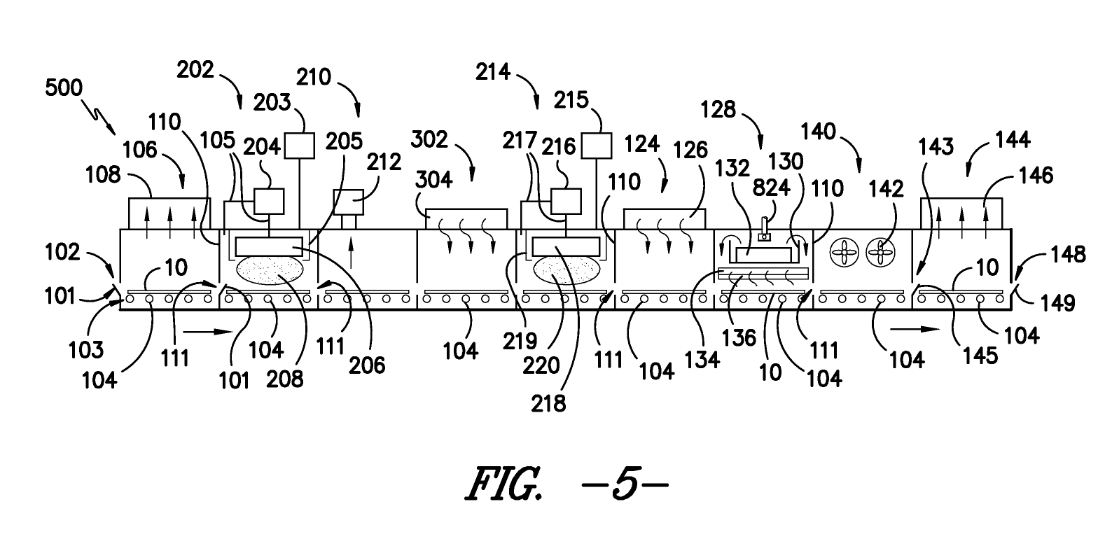

However, in an alternative embodiment such as shown in the systems 400 and 500 of FIGS. 4 and 5, respectively, a second vacuum chamber can be omitted between the second vacuum buffer chamber 222 and subsequent chambers (e.g., the optional heating chamber 124 or the vapor deposition chamber 128). The systems 400, 500 of FIGS. 4 and 5 are otherwise identical to the systems 200, 300 of FIGS. 2 and 3, respectively. In these embodiments, a small amount of particulates may transfer between the first sputtering deposition chamber 202 and the vapor deposition chamber 128, particularly in the ends closest to the adjacent chambers. Such as small amount of mixing, which may be desirable when forming subsequent a cadmium sulfide layer in the second sputtering deposition chamber 214 and the cadmium telluride layer in the vapor deposition chamber 128 in order to form an intermixed area between the cadmium sulfide layer and the cadmium telluride layer.

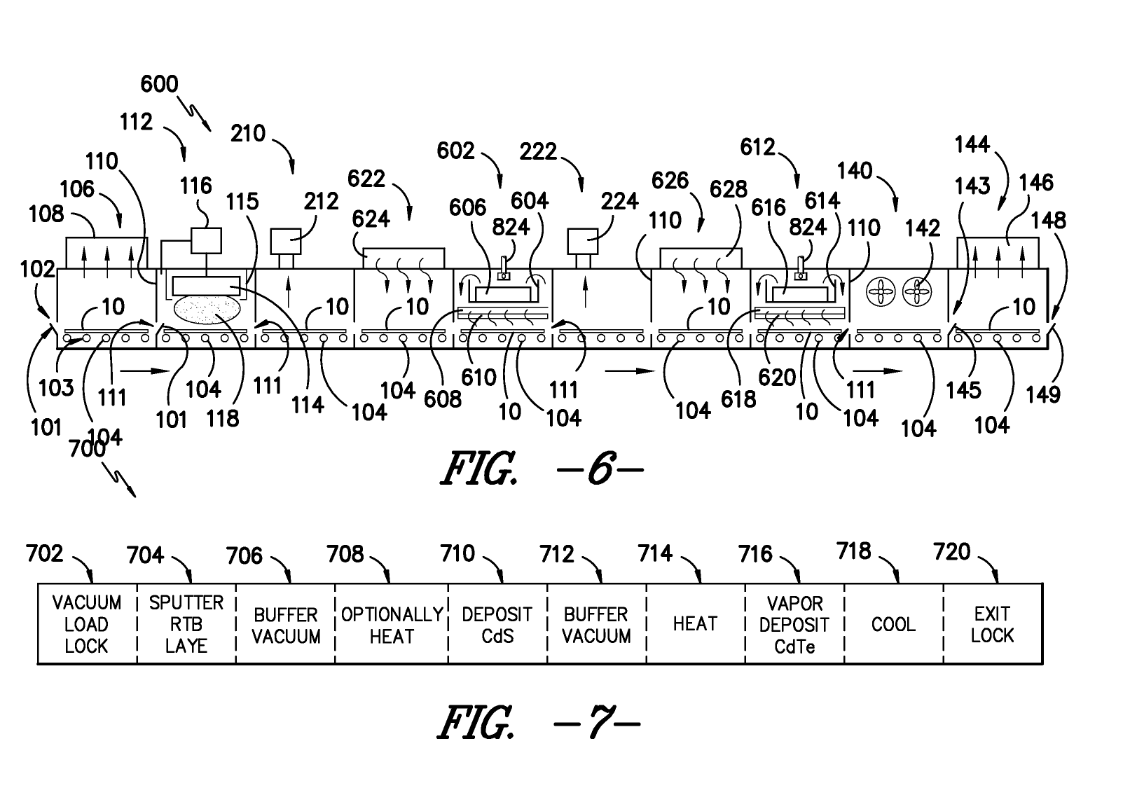

The exemplary embodiment of system 600 shown in FIG. 6 includes a sputtering deposition chamber 112, a first vapor deposition chamber 602, and a second vapor deposition chamber 612. In this embodiment, the sputtering deposition chamber 112 can be utilized to deposit the RTB layer on the substrate; the first vapor deposition chamber 602 can be utilized to deposit the cadmium sulfide layer over the RTB layer; and, the second vapor deposition chamber 612 can be utilized to deposit the cadmium telluride layer. The first vapor deposition chamber 602 and the second vapor deposition chamber 612 can be constructed to include the vapor deposition apparatus 800 shown in FIGS. 8 and 9.

Referring to FIG. 6, substrates 10 can enter the first vapor deposition chamber 602 to deposit the second thin film layer, after sputtering the first thin film in the sputtering deposition chamber 112. The first heating manifold 608 can heat the first source material 606 (e.g., cadmium sulfide) in the first receptacle 604 into vapors. The vapors of the first source material 606 can flow through the first heating manifold 608 and the first deposition plate 610.

The substrates 10 can be then transferred through the optional second vacuum buffer chamber 222 and the optional second heating chamber 626 and into the second vapor deposition chamber 612. The second source material 616 (e.g., cadmium telluride) in the second receptacle 614 can be heated into vapor by the second heating manifold 618. The vapors can pass through the second heating manifold 618 and the second deposition plate 620 and deposit onto the substrates 10 as a third thin film (e.g., a cadmium telluride layer).

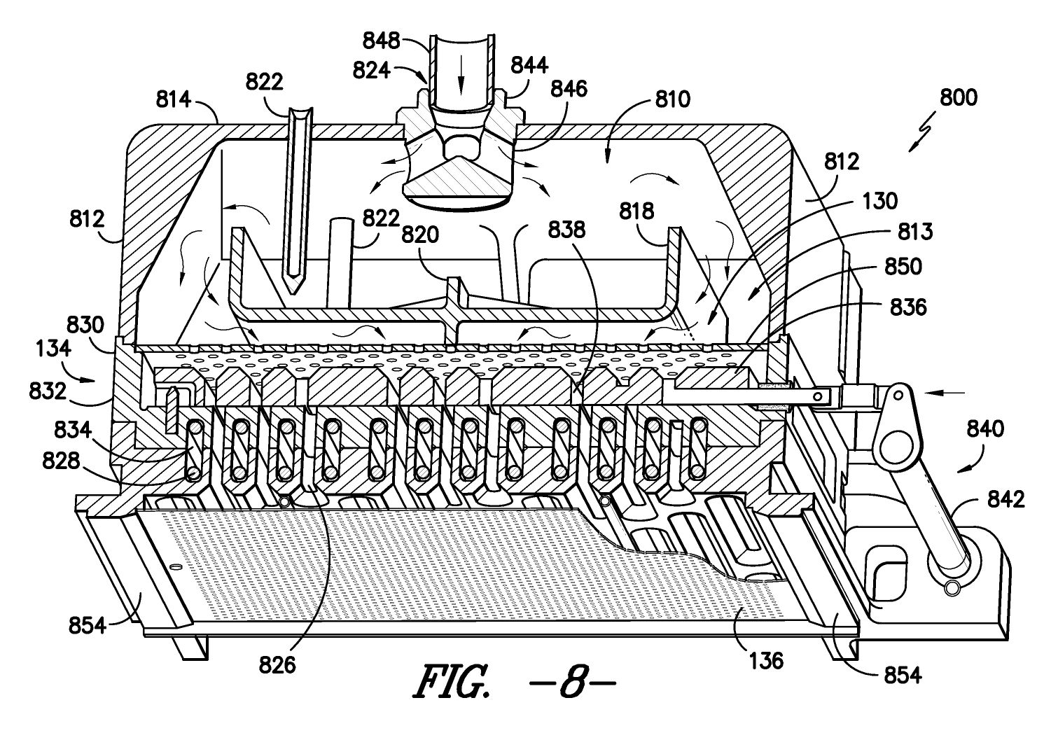

As stated, the presently disclosed methods and systems are particularly suitable for increasing the efficiency and/or consistency of in-line manufacturing of cadmium telluride thin film photovoltaic devices, such as in the cadmium telluride thin film photovoltaic device. FIG. 7 shows an exemplary process 700 of depositing thin film layers on a substrate to form a cadmium telluride based PV device according to one embodiment of the present invention. The process 700 can be utilized to sequentially deposit a cadmium sulfide (CdS) layer and a cadmium telluride (CdTe) layer on a substrate (e.g., a glass superstrate). Optionally, a resistive transparent buffer layer (“RTB layer”) can be deposited on the substrate (e.g. onto a transparent conductive oxide layer) prior to depositing the cadmium sulfide layer.

According to the exemplary process 700 shown in FIG. 7, the substrate can first pass a load vacuum chamber 702 where a vacuum can be drawn to the desired system pressure (e.g., a load vacuum pressure) to separate the system atmosphere within the entire process system 700 from the surrounding atmosphere.

Then, the substrate can be passed into the RTB layer deposition chamber 704 to deposit a resistive transparent buffer layer (RTB layer) onto the substrate. For example, the RTB layer can be deposited onto a transparent conductive oxide (TCO) layer on the substrate. The TCO layer can have a sheet resistance less than about 30 ohm per square, such as from about 4 ohm per square to about 20 ohm per square (e.g., from about 8 ohm per square to about 15 ohm per square). The TCO layer generally includes at least one conductive oxide, such as tin oxide, zinc oxide, or indium tin oxide, or mixtures thereof. Additionally, the TCO layer can include other conductive, transparent materials. The TCO layer can also include zinc stannate and/or cadmium stannate.

The RTB layer can be positioned between the TCO layer and the cadmium sulfide layer to allow for a relatively thin cadmium sulfide layer to be included in the device by reducing the possibility of interface defects (i.e., “pinholes” in the cadmium sulfide layer) creating shunts between the TCO layer and the cadmium telluride layer. The RTB layer can include, for instance, a combination of zinc oxide (ZnO) and tin oxide (SnO₂), which can be referred to as a zinc tin oxide layer (“ZTO”). In one particular embodiment, the RTB layer can include more tin oxide than zinc oxide. In certain embodiments, the RTB layer can be deposited to a thickness between about 0.075 μm and about 1 μm, for example from about 0.1 μm to about 0.5 μm.

After deposition of the RTB layer, the substrate can pass through a first buffer vacuum chamber 706 to remove any particles from the substrate and/or chamber atmosphere before depositing subsequent layers. The substrate can then be optionally heated in the first heating chamber 708, depending on the deposition technique of the CdS layer, prior to deposition of the CdS layer. The CdS layer can then be deposited on the substrate in the CdS deposition chamber 710 (e.g., sputtering a target of cadmium sulfide or vapor deposition of a source material of cadmium sulfide).

The cadmium sulfide layer is a n-type layer that generally includes cadmium sulfide (CdS) but may also include other materials, such as zinc sulfide, cadmium zinc sulfide, etc., and mixtures thereof as well as dopants and other impurities. Due to the presence of the resistive transparent layer 16, the cadmium sulfide layer 18 can have a thickness that is less than about 0.1 μm, such as between about 10 nm and about 100 nm, such as from about 50 nm to about 80 nm, with a minimal presence of pinholes between the resistive transparent layer 16 and the cadmium sulfide layer 18. Additionally, a cadmium sulfide layer 18 having a thickness less than about 0.1 μm reduces any adsorption of radiation energy by the cadmium sulfide layer 18, effectively increasing the amount of radiation energy reaching the underlying cadmium telluride layer 20.

After deposition of the CdS layer, the substrate can pass through a second buffer vacuum chamber 712 to remove any particles from the substrate and/or chamber atmosphere before depositing the CdTe layer. The substrate can then be optionally heated in the second heating chamber 714, depending on the deposition technique of the CdTe layer, prior to deposition of the CdTe layer.

The CdTe layer can then be deposited on the substrate in the CdTe deposition chamber 716 (e.g., vapor deposition of a source material of cadmium telluride). The cadmium telluride layer is a p-type layer that generally includes cadmium telluride (CdTe) but may also include other materials. As the p-type layer of device 10, the cadmium telluride layer 20 is the photovoltaic layer that interacts with the cadmium sulfide layer 18 (i.e., the n-type layer) to produce current from the adsorption of radiation energy by absorbing the majority of the radiation energy passing into the device 10 due to its high absorption coefficient and creating electron-hole pairs. The p-n junction formed between the cadmium sulfide layer and the cadmium telluride layer forms a diode-like material that allows conventional current to flow in only one direction to create a charge imbalance across the boundary. This charge imbalance leads to the creation of an electric field spanning the p-n junction and separating the freed electrons and holes. In particular embodiments, the cadmium telluride layer can be deposited to a thickness between about 0.1 μm and about 10 μm, such as from about 1 μm and about 5 μm. In one particular embodiment, the cadmium telluride layer 20 can have a thickness between about 2 μm and about 4 μm, such as about 3 μm.

The substrate can then be cooled in the cooling chamber 718, and can pass through an exit lock chamber 720 to bring the atmosphere back to a room pressure.

Each of the chambers 702-720 are integrally interconnected together such that the substrates passing through the chambers 702-720 according to the process 700 are substantially protected from the outside environment. In other words, the component sections of the process 700 are directly integrated together such that a substrate exiting one component section immediately enters the adjacent section. Thus, the process 700 is shown having interconnected steps to represent that the devices are transferred from one step to the next step directly, without exposure to the room atmosphere. Thus, the substrates can be protected from outside contaminants being introduced into the thin films, resulting in more uniform and efficient devices. Of course, other intermediary steps may be included within the process 700, as long as the steps are also interconnected to the other steps of the process 700.

Through the integration of these deposition processes into a single system, the energy consumption required for the deposition of the RTB layer, the CdS layer, the CdTe layer can be reduced, when compared from separated deposition systems. For instance, once the load vacuum is drawn in the load lock step 702, no need for an additional load vacuum step exists, since the system pressure can remain at or below the load vacuum pressure (e.g., less than about 250 mTorr).

Various combinations of deposition processes (e.g., sputtering, sublimation, etc.) can be used to deposit the various thin film layers (i.e., the RTB layer, the CdS layer, and/or the CdTe layer) according to the integrated process 700, as shown in the systems 100, 200, 300, 400, 500, and 600 of FIGS. 1-6, respectively.

Of course, other post-forming treatments can be applied to the exposed surface of the cadmium telluride layer (e.g., cadmium chloride treatment, back contact deposition, encapsulating glass, bus bars, external wiring, laser etches, etc).

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1-10. (canceled)

11. A process of manufacturing a thin film cadmium telluride thin film photovoltaic device, the process comprising:
transporting a substrate into a load vacuum chamber connected to a load vacuum pump;
drawing a vacuum in the load vacuum chamber using the load vacuum pump until an initial load pressure is reached in the load vacuum chamber;
transporting the substrate from the load vacuum chamber into a sputtering deposition chamber, wherein the sputtering deposition chamber comprises a target that comprises cadmium sulfide;
sputtering the target to deposit a cadmium sulfide layer on the substrate in a sputtering atmosphere including a plasma, wherein the plasma ejects atoms from the target to deposit onto the substrate;
transporting the substrate from the sputtering deposition chamber into a vacuum buffer chamber connected to a buffer vacuum pump;
drawing a vacuum in the vacuum buffer chamber using the buffer vacuum pump to form a buffer atmosphere, wherein the buffer vacuum pump removes residual atoms ejected from the target from the buffer atmosphere;
transporting the substrate from the vacuum buffer chamber into a vapor deposition chamber comprising a source material, wherein the source material comprises cadmium telluride; and,
depositing a cadmium telluride layer on the cadmium sulfide layer by heating the source material to produce source vapors that deposit onto the cadmium sulfide layer on the substrate,
wherein the substrate is transported through the load vacuum chamber, the sputtering deposition chamber, the vacuum buffer chamber, and the vapor deposition chamber at a system pressure less than 760 Torr.

12. The process as in claim 11, wherein the vapor deposition chamber comprises a receptacle for holding a the source material, a heating manifold for heating the receptacle such that the source material vaporizes into source vapors, and a deposition plate defining holes through which the source vapors pass for deposition of the cadmium telluride layer over the cadmium sulfide layer on the substrate.

13. The process as in claim 11, wherein the vacuum buffer chamber further comprises heaters configured to heat the substrate to a vapor deposition temperature.

14. The process as in claim 11, further comprising:
transporting the substrate from the vacuum buffer chamber into a heating chamber;
heating the substrate to a vapor deposition temperature; and, transporting the substrate from the heating chamber to the vapor deposition chamber.

15. The process as in claim 11, further comprising:
transporting the substrate from the load vacuum chamber into a preliminary sputtering chamber;
sputtering a resistive transparent layer on the substrate;
transporting the substrate from the preliminary sputtering chamber into the sputtering deposition chamber to deposit a cadmium sulfide layer on the resistive transparent layer.

16. The process as in claim 15, wherein the preliminary sputtering deposition chamber comprises a preliminary target, wherein the preliminary target is sputtered to deposit a resistive transparent layer on the substrate, the resistive transparent layer comprising zinc tin oxide.

17-20. (canceled)
